(19) United States
(12) Patent Application Publication
(10) Pub. No.: US 2011/0278616 A1
(43) Pub. Date: Nov. 17, 2011

(54) MANUFACTURING METHOD OF WAVELENGTH CONVERSION ELEMENT, WAVELENGTH CONVERSION ELEMENT, AND LIGHT EMITTING DEVICE

(76) Inventors: Takashi Washizu, Tokyo (JP); Takuji Hatano, Osaka (JP); Yoshihito Taguchi, Amagasaki-shi (JP)

(21) Appl. No.: 13/104,222

(22) Filed: May 10, 2011

(30) Foreign Application Priority Data
May 11, 2010 (JP) 2010-109146

(51) Int. Cl. H01L 33/58; H01L 21/78

(52) U.S. Cl. 257/98; 438/460; 257/E21.599; 257/E33.06

(57) ABSTRACT

A manufacturing method of a wavelength conversion element suppresses the changes of the chromaticities among wavelength conversion elements. The manufacturing method of the wavelength conversion element including a glass substrate and a ceramic layer in which a phosphor is dispersed is disclosed. The manufacturing method includes the step of preparing a mixture containing a ceramic precursor, a solvent, and the phosphor, which mixture has viscosity within a range of from 10 cp to 1000 cp, the step of coating the mixture onto at least one surface of a glass substrate, the step of baking the mixture to form the ceramic layer, and the step of dicing the glass substrate and the ceramic layer after the baking.

### BACKGROUND OF THE INVENTION

1. Field of the Invention

The present invention relates to a manufacturing method of a wavelength conversion element, a wavelength conversion element, and a light emitting device.

2. Description of Related Art

A light emitting device obtaining a white light by making a phosphor emit a light by means of a light from a light emitting diode (LED) element as an excitation light has hitherto been developed in the uses of illumination and the like.

As such a light emitting device, for example, a light emitting device using a phosphor emitting a yellow light generated by a blue light emitted from an LED element to make a white light by mixing the color of each light with each other, a light emitting device using a phosphor emitting a blue light, a green light, and a red light generated by an ultraviolet light emitted from an LED element to make a white light by mixing the three color lights emitted from the phosphor with one another, and the like are known.

Although a light emitting device made by directly sealing an LED chip with a hardening resin in which a phosphor is dispersed has been developed as a configuration of such a light emitting device, the uses of the light emitting device have expanded to a region in which high luminance is required like a headlight of an automobile or the like, and now the heightening of the output power of white LED's has advanced to cause the heat generation of their LED chips. Consequently, if a phosphor is directly provided on an LED element in the form of being dispersed in a sealing medium as described above, the phosphor sometimes thermally deteriorates owing to the heat generation of the LED element.

Moreover, because resins cannot prevent the permeation of moisture, the deterioration of the phosphor by moisture is also a problem.

A technique of preventing the deterioration of a sealing medium by dispersing a phosphor not into a resin but into a ceramic to seal an LED was proposed in order to settle such problems (for example, Japanese Patent Application Laid-Open Publication No. 2000-349347).

However, it is difficult to form a thin film of a film thickness of several hundreds pm or more by using the ceramic precursor described in Japanese Patent Application Laid-Open Publication No. 2000-349347 owing to the characteristic thereof. If the whole LED is covered (sealed) by the thin film, cracks are produced, and a light emitted from the LED is scattered by the cracks to cause color shifts and color shading.

Accordingly, the present inventors made a phosphor element isolated from an LED by coating a material containing a phosphor onto a substrate made of glass or the like, baking the material, and forming a ceramic layer on the substrate. By trying to convert the wavelength of a light from the LED by using the phosphor element as a “wavelength conversion element,” the inventors were able to thin the layer thickness of the ceramic layer and suppress the generation of cracks. Moreover, a light emitting device using a phosphor element manufactured by such a method as a wavelength conversion element was capable of greatly decreasing color shifts and color shading generated according to emission angles in comparison with the conventional case where an LED was directly sealed with a sealing medium containing phosphor particles therein.

Moreover, when a wavelength conversion element was manufactured as an isolated body, it became possible to evaluate the performance of an LED and the characteristic of a wavelength conversion element separately, and to assemble them to make a light emitting device. Then, it was possible to improve the yield at the time of manufacturing the light emitting device.

In order to further improve the productivity, the present inventors tried a method of coating a material containing a phosphor onto a substrate, baking the substrate with the material, and providing a ceramic layer. After that, the method cut (diced) the substrate into small pieces to manufacture a phosphor element. However, when the inventors measured the chromaticity of each light emitting device combining the wavelength conversion element and an LED, the inventors found that the chromaticities were different from one another among the light emitting devices (wavelength conversion elements).

Accordingly, the present inventors further examined this problem, and, as a result of the examination, the inventors found that the differences among chromaticities were brought about by the unevenness of the thickness of coating at the step of the coating of the material containing the phosphor, which unevenness was fixed by being subjected to the baking. This problem was not actualized in the state of a phosphor element before being cut because the chromaticities were averaged as a whole, although some color shading was brought about owing to the unevenness of the thickness of coating. However, it was considered that the cutting of the phosphor element had changed it to be small pieces, and the differences of the thicknesses of the coatings of the pieces exerted the influences on the chromaticities of the respective small pieces greatly to actualize the problem. The inventors tried coatings by various coating techniques for this problem of the unevenness of such thicknesses of coatings, but it was difficult to suppress the dispersion of the chromaticities sufficiently.

### SUMMARY OF THE INVENTION

It is therefore a main object of the present invention to provide a manufacturing method of a wavelength conversion element which method can decrease the problems of color shading and color shifts and is excellent in productivity to enable the suppressing of the changes of the chromaticities among wavelength conversion elements, and at the same time, it is also the object of the present invention to provide a wavelength conversion element manufactured by the manufacturing method of the wavelength conversion element and a light emitting device using the wavelength conversion element.

According to an aspect of the present invention for settling the problems mentioned above, a manufacturing method of a wavelength conversion element including a substrate and a ceramic layer with a phosphor dispersed therein includes the steps of: preparing a mixture containing a ceramic precursor, a solvent, and the phosphor, the mixture having viscosity in a range of from 10 cp to 1000 cp; coating the mixture on at least one surface of the substrate; baking the mixture to form the ceramic layer; and dicing the substrate and the ceramic layer after baking.

According to another aspect of the present invention, a wavelength conversion element manufactured by the manufacturing method of the wavelength conversion element is provided.

According to still another aspect of the present invention, a light emitting device includes: a wavelength conversion element manufactured by the manufacturing method of the wavelength conversion element; and an LED element emitting a light having a specific wavelength to the wavelength conversion element.

According to the present invention, the mixture before baking is adjusted to have a fixed viscosity, and thereby the thickness of coating can be made to be uniform at the time of coating the mixture after the adjustment, and as a result, even when the wavelength conversion element is made by cutting the phosphor element after the formation thereof, the changes of the chromaticities among the small pieces of the wavelength conversion elements can be suppressed.

### BRIEF DESCRIPTION OF THE DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1 is a sectional view showing the schematic configuration of a light emitting device;

FIG. 2 is a view showing a modification of the light emitting device of FIG. 1;

FIG. 3 is a view showing the schematic configuration of a spray coating device;

FIG. 4 is a table showing measurement results and the like of the samples of comparative examples 1 and 2 and examples 1, 2, 3, 4, 5, and 6; and

FIG. 5 is a table showing the results of the measurements of chromaticities in two-dimensional directions (X direction and Y direction) of each cut piece when selected each cut piece is mounted on a blue LED and the LED is made to emit a light.

### DESCRIPTION OF THE PREFERRED EMBODIMENTS

In the following, a preferable embodiment of the present invention will be described with reference to the accompanying drawings.

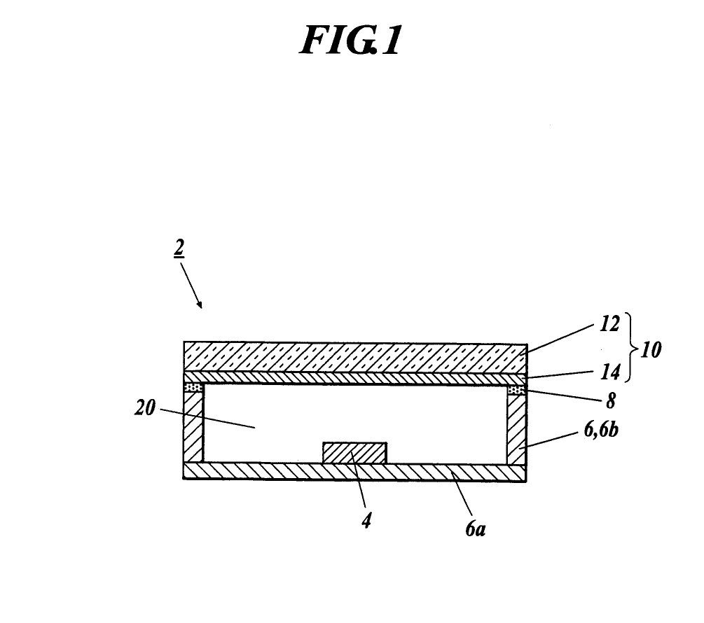

As shown in FIG. 1, a light emitting device 2 includes an LED chip 4 emitting a light of a specific wavelength, an LED housing section 6 housing the LED chip 4, and a wavelength conversion element 10 converting the wavelength of the light of the LED chip 4.

The LED chip 4 is an example of an LED element, and emits a light of a specific wavelength (a blue light in the present embodiment).

As the LED chip 4, a publicly known blue LED chip can be used.

As the blue LED chip, any existing LED chips including InₓGa₁₋ₓN based LED chips can be used. It is preferable that the emission peak wavelength of the blue LED chip is within a range of from 440 nm to 480 nm.

The wavelength of the light emitted by the LED chip 4 and the wavelength of the light emitted by the phosphor in the wavelength conversion element 10 are not limited. That is, any LED chip can be used as the LED chip 4 as long as the wavelength of the light emitted by the LED chip and the wavelength of the light emitted by the phosphor are in a complementary color relation to each other and the light produced by synthesizing both the lights becomes a white light. However, in order to obtain the effect of the present invention, it is preferable that the wavelength of the light emitted by the LED chip 4 and the wavelength of the light emitted by the phosphor are each a visible light.

As the form of the LED chip 4, any form of an LED chip can be applied, such as a type of an LED chip mounted on a substrate to emit light upward or sideward as it is, and the so-called flip-chip interconnection type, in which a blue LED chip is mounted on a transparent substrate, such as a sapphire substrate, and a bump is formed on a surface of the LED chip, following which the LED chip is turned over to be connected to the electrodes on the substrate. But, the flip-chip type one, which is more fitted to the manufacturing methods of a high luminance type one and a lens using type one, is more preferable.

The LED housing section 6 is chiefly composed of a substrate 6a and a side wall 6b to be almost in the shape of a box. The LED chip 4 is mounted on the central part of the substrate 6a. A mirror member made from, e.g., Al or Ag is preferably provided on the internal wall surface of the side wall 6b.

Although be not especially limited, the LED housing section 6 is preferably made from a material that is excellent in light reflectivity and is difficult to deteriorate owing to the light from the LED chip 4.

The wavelength conversion element 10 is provided on the upper part of the LED housing section 6.

The wavelength conversion element 10 is mainly composed of a glass substrate 12 and a ceramic layer 14. The glass substrate 12 is made of a low-melting glass, a metallic glass, or the like. The glass substrate 12 may be one made of a resin. The ceramic layer 14 containing a phosphor is provided on the under surface of the glass substrate 12. The ceramic layer 14 may be provided on both of the under surface and the upper surface of the glass substrate 12.

The ceramic layer 14 is a baked body of a mixture containing a ceramic precursor, a solvent, and a phosphor therein. It is preferable to use a ceramic having a siloxane backbone as the ceramic constituting the ceramic layer 14 of the present invention. In the following, the ceramic precursor (including the solvent) and the phosphor will be described in detail.

### [Ceramic Precursor]

The ceramic precursor including the solvent is a solution containing a metallic compound, but the kind of the metal is not limited as long as the metal can form a ceramic having translucency.

The ceramic precursor solution may be one that gels through a reaction such as hydrolysis and forms a ceramic by heating and baking the gel, or may be one that directly forms a ceramic by volatilizing the solvent component without gelling.

In the former case (sol-gel solution), the metallic compound may be an organic compound or an inorganic compound. As preferable metallic compounds, for example, metal alkoxide, metal acetylacetonato, metal carboxylate, nitrate, and oxide can be cited. Among them, the metal alkoxide is preferable because it easily gels by hydrolysis and polymerization reactions, and tetraethoxysilane is especially preferably used. Moreover, a plurality of kinds of metallic compounds may be combined to be used. Moreover, a metalloxane solution, such as siloxane, can also be used as the ceramic precursor solution.

The sol-gel solution preferably contains water for hydrolysis, solvent, catalyst, and the like suitably besides the metallic compounds mentioned above.

As the solvent, for example, alcohols, such as methanol, ethanol, propanol, and butanol, can be cited.

As the catalyst, for example, hydrochloric acid, sulfuric acid, nitric acid, acetic acid, fluorinated acid, and ammonia can be used.

Moreover, if the sol-gel solution is used as the ceramic precursor solution, the heating temperature at the time of heating the gel is preferably within a range of from 150° C. to 700° C., and is more preferably within a range of from 150° C. to 500° C. from the point of view of more suppressing the deterioration of the glass material and the like to be used as the substrate 6a.

Polysilazane can be used also as a metallic compound to be used for the ceramic precursor solution.

The polysilazane to be used for the present invention can be expressed by the following general formula (1).

(R1R2SiNR3)ₙ . . . (1)

In the formula (1), each of the R1, R2, and R3 independently indicates a hydrogen atom, an alkyl group, an aryl group, a vinyl group, and a cycloalkyl group, and at least one of the R1, R2, and R3 is a hydrogen atom. Preferably, all of the R1, R2, and R3 are hydrogen atoms, and n indicates an integer of from 1 to 60.

The molecular shape of the polysilazane may be any shape, and, for example, may be a straight chain or a ring.

The polysilazane expressed by the formula (1) and a reaction accelerator, as needed, are melted in an appropriate solvent to be coated. After the coating, the coating is cured by performing heating processing, excimer light processing, or ultraviolet (UV) light processing, and thereby a ceramic film being excellent in heat resisting property and light resisting property can be produced. In particular, if heat curing is performed after curing the coating by radiating an ultra-violet and/or vacuum ultra-violet (UVU) radiation (for example, excimer light) containing a wavelength component within a range of from 170 nm to 230 nm, then the permeation prevention effect of moisture can further be improved.

As the reaction accelerator, it is preferable to use an acid, a base, and the like, but the acid, the base, and the like need not be used. As the reaction accelerator, for example, triethylamine; diethylamine; N,N-diethylethanolamine; N,N-dimethyleethanolamine; triethanolamine; triethylamine; hydrochloric acid; oxalic acid; fumaric acid; sulfonic acid; acetic acid; metallic carboxylates containing nickel, iron, palladium, iridium, platinum, titanium, and aluminium; and the like, can be cited, but the reaction accelerator is not limited to the ones mentioned above.

The metallic carboxylates are especially preferable at the time of using a reaction accelerator, and the additive amount is preferably within a range of from 0.01 mol % to 5 mol % on the basis of polysilazane.

As the solvent, aliphatic hydrocarbons, aromatic hydrocarbons, halogen hydrocarbons, ethers, and esters can be used. The solvent is preferably one of methyl ethyl ketone, tetrahydrofuran, benzene, toluene, xylene, dimethylfluoride, chloroform, carbon tetrachloride, ethyl ether, isopropyl ether, dibutyl ether, and ethyl butyl ether.

Moreover, the concentration of polysilazane is preferable to be high, but a rise of the concentration leads to the shortening of the preservation period of the polysilazane. Accordingly, it is preferable that the polysilazane dissolves in the solvent to be the ratio of from 5 wt % to 50 wt % (% by weight) or less.

Moreover, if the polysilazane solution is used as the ceramic precursor solution, then from the point of view of suppressing the deterioration of the glass material and the like used as the substrate, the heating temperature at the time of baking is preferably within a range of from 150° C. to 500° C., more preferably a range of from 150° C. to 350° C.

### [Phosphor]

The phosphor converts a light of a first predetermined wavelength emitted from the LED chip 4 into a light of a second predetermined wavelength. The present embodiment is adapted to convert a blue light emitted from the LED chip 4 into a yellow light.

As such a phosphor, a sintered body formed by being subjected to the following process of (A1) or (A2) and the following process of (B) is preferably used.

(A1): The oxides of Y, Gd, Ce, Sm, Al, La, and Ga, or compounds that are easily oxidized at a high temperature are sufficiently mixed at stoichiometric mixture ratios to obtain a mixed raw material.

(A2): Rare earth elements of Y, Gd, Ce, and Sm are dissolved with an acid at stoichiometric mixture ratios, and the solution is coprecipitated with oxalic acid. The coprecipitation oxide obtained by baking the coprecipitated solution, aluminium oxide, and gallium oxide are mixed to obtain a mixed raw material.

(B): A proper quantity of fluoride of ammonium fluoride or the like is mixed as a flux with either of the mixed raw materials obtained by the processes of (A1) and (A2), and a compact is obtained by pressurizing the mixture. After that, the compact is stuffed in a crucible, and is baked in the air within a temperature range of from 1350° C. to 1450° C. for two to five hours. Thereby, a sintered body having a luminous characteristic of a phosphor can be obtained.

Although an yttrium aluminum garnet (YAG) phosphor is used in the present embodiment, the kind of the phosphor is not limited to the above-mentioned one. As the phosphor, another phosphor, such as a nongarnet series phosphor, not including Ce can also be used.

The larger the particle diameters of the phosphor are, the higher the luminous efficiency (wavelength conversion efficiency) thereof becomes. On the other hand, the larger the particle diameters are, the larger the gaps produced at interfaces between the particles and the organic metallic compound become, and the lower the film strength of the formed ceramic layer 14 becomes. Accordingly, the phosphor having an average particle diameter within a range of from 1 μm to 50 μm is preferably used in consideration of the luminous efficiency and the sizes of the gaps formed at the interfaces between the phosphor and the organic metallic compound. The average particle diameter of the phosphor can be measured by, for example, the Coulter Counter method.

The ceramic layer 14 preferably has a thickness within a range of from 5 μm to 200 μm.

Although the lower limit value of the thickness of the ceramic layer 14 is not limited, the permeation prevention effect of moisture can be obtained when the thickness of the ceramic layer 14 is thicker than that of the phosphor particles, and the deterioration of the phosphor particles can be suppressed.

The reason why the upper limit value of the thickness of the ceramic layer 14 is 200 μm is that there is a possibility that cracks are generated in the ceramic layer 14 when the thickness exceeds the value, and that the upper limit value is set for preventing the generation of the cracks.

In the light emitting device 100, an adhesive 8 is coated on the upper part of the side wall 6b of the LED housing section 6, and the wavelength conversion element 10 is adhered to the side wall 6b. As a result, an enclosed space 20 is formed in a region enclosed by the LED housing section 6 and the ceramic layer 14, and the LED chip 4 is contained in the enclosed space 20. Hence, the deterioration of the LED chip 4 owing to the oxygen and humidity in the open air is suppressed.

The enclosed space 20 is preferably formed to be a low refractive index layer having a lower refractive index than that of the glass substrate 12. As the low refractive index layer, for example, a gas layer with gas filled up therein, an air layer, or a resin layer is preferable. As the gas layer, for example, a gas, such as a nitrogen gas, is preferably purged. By forming the gas layer as the low refractive index layer, a light emitted from the phosphor to the side of the glass substrate 12 is easily totally reflected on the internal wall surface of the side wall 6b of the LED housing section 6, and the arrangement becomes the one in which the utilization efficiency of a light emitted from the phosphor is high.

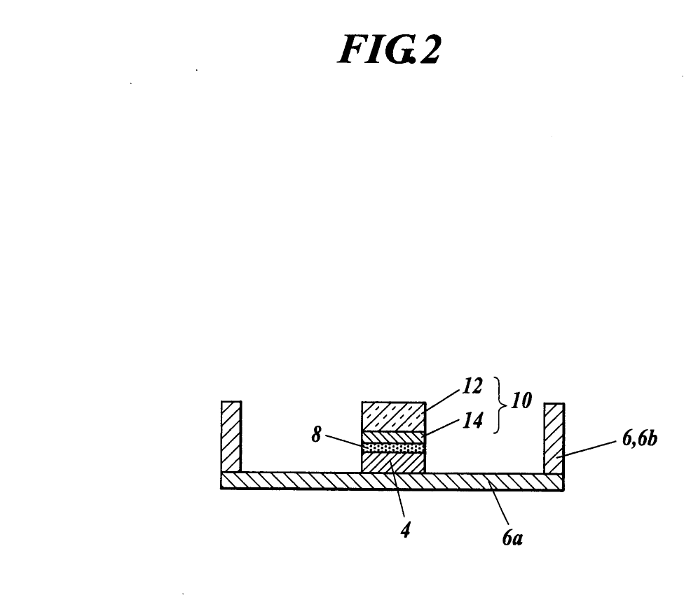

In the light emitting device 2, as shown in FIG. 2, the adhesive 8 may directly be coated onto the LED chip 4 to adhere the wavelength conversion element 10 thereto.

Successively, the operation of the light emitting device 2 will simply be described.

First, when the LED chip 4 emits a blue light to the outside, the blue light enters the phosphor in the ceramic layer 14. Then, a yellow light is emitted from the phosphor excited by the blue light. As a result, the blue light and the yellow light generated by the phosphor are superposed on each other to be a white light to be emitted to the outside of the LED housing section 6.

The light emitting device 2 mentioned above can preferably be used as a headlight for an automobile.

Successively, a manufacturing method of the light emitting device 2 will simply be described.

First, a ceramic precursor, a solvent, and a phosphor are mixed to prepare a predetermined mixture. In this case, thickening processing for increasing the viscosity of the mixture is performed to the mixture, and the viscosity is thereby adjusted to be within a range of from 10 cp to 1000 cp, preferably within a range of from 15 cp to 200 cp.

As the thickening processing (method), for example, the following three methods (1), (2), and (3) can be cited. The methods (1)-(3) may independently be used or may be used in combination with one another.

Any technique can be used as long as the technique can perform thickening, and consequently the method cannot be limited to the ones (1)-(3).

### (1) Method of Adding Inorganic Particles

In this method, “inorganic particles” are added to the mixture.

The inorganic particles not only have the thickening effect of increasing the viscosity of the mixture, but also have a filling-up effect of filling up the gaps produced at the interfaces between the organic metallic compound and the phosphor, and the effect of improving the film strength of the ceramic layer 14 after being heated.

As the inorganic particles used for the present invention, oxide particles of silicon oxide, titanium oxide, zinc oxide, and the like, and fluoride particles of magnesium fluoride and the like can be cited. In particular, if an organic metal compound containing silicon therein, such as polysiloxane, is used as the organic metallic compound, oxide particles of silicon oxide is preferably used as the inorganic particles from the point of view of the stability for the ceramic layer 14 to be formed.

The contained amount of the inorganic particles in the ceramic layer 14 is preferably within a range of from 0.5 wt % to 50 wt %, further preferably within a range of from 1 wt % to 40 wt %.

If the contained amount of the inorganic particles is less than 0.5 wt %, the respective effects mentioned above cannot sufficiently be obtained. On the other hand, if the contained amount of the inorganic particles exceeds 50 wt %, the strength of the ceramic layer 14 after being heated falls.

In consideration of the respective effects mentioned above, it is preferable to use the inorganic particles having an average particle diameter within a range of from 0.001 μm to 50 μm, and is more preferably to use the ones having an average particle diameter within a range of from 0.001 μm to 1 μm. The average particle diameter of the inorganic particles can be measured by, for example, the Coulter Counter method.

### (2) Method of Using Layered Silicate Mineral

In this method, “layered silicate mineral” is added to the mixture.

As the layered silicate mineral, expansive clay minerals having the structures of a mica structure, a kaolinite structure, a smectite structure, and the like are preferable. The smectite structure, which is rich in swelling property, is particularly preferable. The reason is that when water is added to the mixture, the water enters the spaces between the layers of the smectite structure to make the smectite structure a swollen card house structure, and that the smectite structure has an effect of greatly increasing the viscosity of the mixture.

The contained amount of the layered silicate mineral in the ceramic layer 14 is preferably within a range of from 0.5 wt % to 20 wt %, and more preferably within a range of from 0.5 wt % to 10 wt %.

When the contained amount of the layered silicate mineral is less than 0.5 wt %, the effect of increasing the viscosity of the mixture cannot sufficiently be obtained. On the other hand, when the contained amount of the layered silicate mineral exceeds 20 wt %, the strength of the ceramic layer 14 after being heated falls.

If an organic solvent is used as the solvent, it is preferable to perform the modification (surface processing) of the surface of the layered silicate mineral with an ammonium salt in consideration of the compatibility with the organic solvent.

If a thickening agent is added as described in the methods (1) and (2), it is necessary to adjust the mixing quantity of the thickening agent and the phosphor in order that the ceramic layer 14 generated after baking may be within a range of from 5 wt % to 60 wt % from the point of view of the film strength of the ceramic layer 14.

### (3) Method of Advancing Reaction to Thicken

In this method, the viscosity of a mixture is thickened by increasing the molecular weight of organic metal alkoxide and polysilazane, which are ceramic precursors (derivatives).

In this case, it is possible to increase the molecular weight of the ceramic precursor to thicken the mixture by “advancing the reaction” (for example, by heating and stirring the mixture) within a range in which the ceramic precursor can be dissolved in the solvent.

After that, the ceramic layer 14 is formed by coating the mixture after the adjustment of the viscosity thereof onto the glass substrate 12 to bake the coating at a certain temperature and for a certain time.

When the mixture is coated on the glass substrate 12, any coating technique can be used, and for example, the following coating techniques (i)-(iii) can preferably be used.

### (i) Applicator (Blade)

The mixture can be coated on the glass substrate 12 by using a publicly known applicator. For example, as a concrete applicator, Baker Applicator manufactured by Kodaira Seisakusyo Co., Ltd. can be used.

If an applicator is used, the preferable moving speed of the applicator is set to be within a range of from 0.1 m/min. to 3.0 m/min.

### (ii) Spin Coater

The mixture can be coated on the glass substrate 12 by using a publicly known spin coater. For example, as a concrete spin coater, Spin Coater MS-A100 manufactured by Mikasa Co., Ltd. can be used.

If the spin coater is used, the rotation speed is preferably set to be within a range of from 1000 rpm to 3000 rpm and the rotation time is preferably set to be within a range of from 5 sec. to 20 sec.

(iii) Spray Coating Device

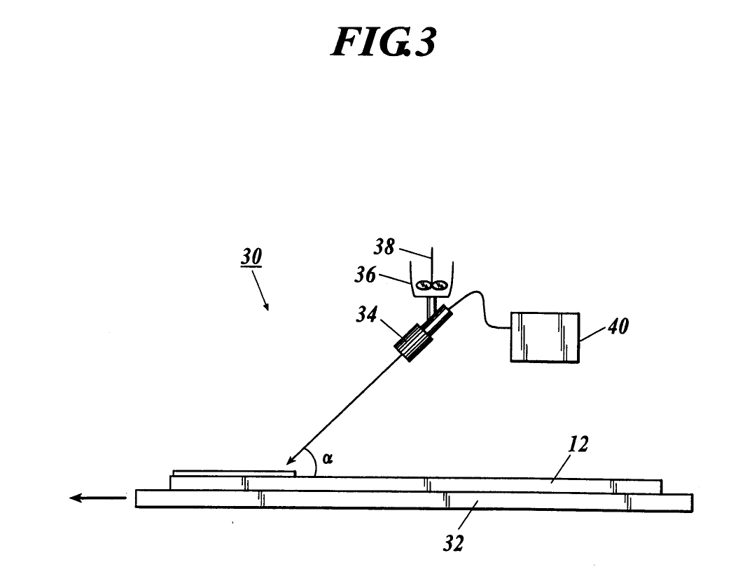

The mixture can be coated on the glass substrate 12 by using the spray coating device 30 of FIG. 3.

As shown in FIG. 3, the spray coating device 30 includes a movable pedestal 32. The glass substrate 12 is installed on the pedestal 32. A nozzle 34 ejecting the mixture is provided above the pedestal 32. A tank 36 for reserving the mixture is connected to the nozzle 34. A stirring mechanism 38 for stirring the mixture is installed on the inside of the tank 36. A compressor 40 for sending the mixture into the nozzle 34 to make the mixture be ejected from the nozzle 34 is connected to the nozzle 34.

For example, spray gun W-101-142 BPG manufactured by Anest Iwata Corp. can be used as the concrete nozzle 34, and PC-51 manufactured by Anest Iwata Corp. can be used as the concrete tank 36, and OFP-071C manufactured by Anest Iwata Corp. can be used as the concrete compressor 40.

When the mixture is actually coated on the glass substrate 12 by using the spray coating device 30, the pedestal 32 is moved while the mixture is being ejected from the nozzle 34 by the compressor 40 in the state in which the mixture in the tank 36 is being stirred by the stirring mechanism 38. Thereby, the mixture is coated on the glass substrate 12 while the coating position of the mixture is being changed.

In this case, the moving speed of the pedestal 32 is preferably set to be within a range of from 10 mm/sec to 60 mm/sec.

If the moving speed of the pedestal 32 is set within the range of from 10 mm/sec to 60 mm/sec, the mixture can uniformly be coated on the glass substrate 12.

The ejection angle α of the nozzle 34 to the glass substrate 12 is preferably set within a range of from 30° to 60°.

The longer the distance between the glass substrate 12 and the nozzle 34 is, the more uniformly the mixture can be coated. However, because the film strength of the ceramic layer 14 has also a tendency to fall, the distance between the glass substrate 12 and the nozzle 34 is preferably set to be within a range of from 3 cm to 30 cm.

The distance between the glass substrate 12 and the nozzle 34 can be adjusted within the range mentioned above in consideration of the pressure of the compressor 40. In the present embodiment, the pressure of the compressor 40 can be adjusted in order that the pressure at the jetting port of the nozzle 34 may be, for example, 0.14 MPa.

In the coating technique described above, the thickness of coating can be made to be uniform by adjusting the viscosity of the mixture to be 10 cp or more.

If the viscosity of the mixture is adjusted to be within a range of from 10-1000 cp, the coating by the spray coating method of (iii) described above becomes possible, and the coating having a uniform thickness of coating becomes possible.

If the viscosity of the mixture exceeds 1000 cp, the irregularities of the mixture and movement traces (stripes) of the applicator remain after the coating thereof, and there is a possibility that the uniformity of the thickness of the coating of the mixture decreases. Accordingly, the viscosity of the mixture is preferably set to be 1000 cp or less.

After that, the glass substrate 12 on which the ceramic layer 14 is formed is diced into pieces each formed in a polygon (for example, quadrilateral) having one side of about 5 mm, and a plurality of wavelength conversion elements 10 is thus manufactured. After that, the adhesive 8 is coated onto the LED housing section 6 to which the LED chip 4 is mounted beforehand, and the wavelength conversion element 10 is adhered thereto.

According to the present embodiment described above, the viscosity of a liquid mixture of a ceramic precursor, a solvent, and a phosphor is adjusted to be constant, and consequently the thickness of coating of the mixture can be made to be uniform when the mixture is coated on the glass substrate 12. As a result, the thickness of the ceramic layer 14 of each wavelength conversion element 10 after dicing becomes uniform, and the changes of chromaticities among wavelength conversion elements 10 can be suppressed independent of coating techniques (see the following examples).

### EXAMPLES

### (1) Making Samples

With an aim of manufacturing a plurality of light emitting devices each having the configuration essentially same as that of FIG. 1, the manufacturing method (coating method, viscosity, and the like) of the ceramic layer of each device was changed.

The details of each configuration were as follows.

### (1.1) LED Chip

A blue LED chip of a size of 1000 μm×1000 μm×100 μm was used, and the blue LED chip was mounted onto a mount member by flip chip mounting.

### (1.2) Preparation of Phosphor

A mixture mixing the following phosphor raw materials was filled up in an aluminum crucible, and a proper quantity of a fluoride, such as ammonium fluoride, was mixed into the mixture as a flux. Then, the mixture was baked within a temperature range of 1350-1450° C. for 2-5 hours in a reducing atmosphere through which a hydrogen containing nitrogen gas was being circulated to obtain a baked product

(Y_{0.72}Gd_{0.24})₃Al₅O₁₂:Ce_{0.04}).
Y₂O₃ . . . 7.41 g
Gd₂O₃ . . . 4.01 g
CeO₂ . . . 0.63 g
Al₂O₃ . . . 7.77 g

After that, the obtained baked product was subjected to pulverization, cleaning, separation, and drying to obtain a desired “phosphor A.” By performing the pulverization of the obtained phosphor A, the phosphor A was made to phosphor particles each having a particle diameter of about 10 μm, and the phosphor particles were used.

An examination of the composition of the phosphor A made it possible to confirm that the phosphor A was a desired phosphor, and an examination of the wavelength of an emitted light in an excitation light having a wavelength of 465 nm made it clear that the emitted light has a peak wavelength of about 570 nm.

### (1.3) Wavelength Conversion Element

### (1.3.1) Comparative Example 1

0.58 g of the phosphor A was mixed into 1 g of “polysiloxane dispersion liquid B (14 wt % of polysiloxane and 86 wt % of isopropyl alcohol)” to make a liquid mixture. The viscosity of the liquid mixture was 2.5 cp.

After that, the liquid mixture was coated onto a glass substrate sized in 50 mm×50 mm with an applicator (blade coater), and the glass substrate was baked at 500° C. for 180 minutes to be a sample of the “comparative example 1.” When the liquid mixture was coated, the thickness of coating of the liquid mixture was adjusted in order that the thickness of the ceramic layer after baking was 30 μm.

### (1.3.2) Comparative Example 2

0.58 g of the phosphor A was mixed into 1 g of the polysiloxane dispersion liquid B to make a liquid mixture, and the liquid mixture was stirred for about 10 minutes while being heated at 50° C. The viscosity of the liquid mixture was 1500 cp. After that, a sample of a “comparative example 2” was made by the processing similar to that of the comparative example 1.

### (1.3.3) Example 1

0.6 g of the phosphor A and 0.03 g of fine particles of an oxide (Nano Tek Powder, SiO₂, manufactured by CIK Nano Tek Corporation; particle diameters: 25 nm) were mixed into 1 g of the polysiloxane dispersion liquid B to make a liquid mixture. The viscosity of the liquid mixture was 12 cp. After that, a sample of the “example 1” was made by the processing similar to that of the comparative example 1.

### (1.3.4) Example 2

0.6 g of the phosphor A and 0.03 g of fine particles of the oxide (Nano Tek Powder, SiO₂, manufactured by CIK Nano Tek Corporation; particle diameters: 25 nm) were mixed into 1 g of the polysiloxane dispersion liquid B to make a liquid mixture. The liquid mixture was stirred for 3 minutes while being heated at 50° C. The viscosity of the liquid mixture was 1000 cp. After that, a sample of the “example 2” was made by the processing similar to that of the comparative example 1.

### (1.3.5) Example 3

0.04 g of Rucentite SWN (smectite manufactured by Co-op Chemical Co., Ltd.) and 0.5 g of pure water were mixed and dispersed. 1.36 g of the polysiloxane dispersion liquid B, 0.96 g of the phosphor A, and 0.4 g of the fine particles of the oxide (Nano Tek Powder, SiO₂, manufactured by CIK Nano Tek Corporation; particle diameters: 25 nm) were mixed into the mixed and dispersed liquid to make a liquid mixture. The viscosity of the liquid mixture was 50 cp. After that, a sample of the “example 3” was made by the processing similar to that of the comparative example 1.

### (1.3.6) Example 4

0.75 g of a polysilazane solution (MN 120-20 wt % (manufactured by AZ Electronic Materials)), 0.8 g of the phosphor A, and 0.05 g of inorganic fine particles (RX 300 manufactured by Nippon Aerosil Co., Ltd.; particle diameters: 7 nm) were mixed to make a liquid mixture. The viscosity of the liquid mixture was 10 cp. After that, a sample of the “example 4” was manufactured by the processing similar to that of the comparative example 1 except for the setting of the baking temperature to 350° C.

### (1.3.7) Example 5

0.04 g of Rucentite SWN (smectite manufactured by Co-op Chemical Co., Ltd) and 0.5 g of pure water were mixed and dispersed. 1.36 g of the polysiloxane dispersion liquid B, 0.96 g of the phosphor A, and 0.4 g of the fine particles of the oxide (Nano Tek Powder, SiO₂, manufactured by CIK Nano Tek Corporation; particle diameters: 25 nm) were mixed to the mixed and dispersed liquid to make a liquid mixture. The viscosity of the liquid mixture was 50 cp. After that, a sample of the “example 5” was made by the processing similar to that of the comparative example 1 except for coating the liquid mixture with a spin coater (at 1500 rpm for 10 seconds).

### (1.3.8) Example 6

0.04 g of Rucentite SWN (smectite manufactured by Co-op Chemical Co., Ltd) and 0.5 g of pure water were mixed and dispersed. 1.36 g of the polysiloxane dispersion liquid B, 0.96 g of the phosphor A, and 0.4 g of the fine particles of the oxide (Nano Tek Powder, SiO₂, manufactured by CIK Nano Tek Corporation; particle diameters: 25 nm) were mixed to the mixed and dispersed liquid to make a liquid mixture. The viscosity of the liquid mixture was 50 cp. After that, a sample of the “example 6” was made by the processing similar to that of the comparative example 1 except for coating the liquid mixture with a spray coater.

### (2) Evaluation of Samples

### (2.1) Measurement of Phosphor Concentration

A samples was scraped off from a measuring position of each ceramic layer, and the concentration (wt %) of the phosphor occupying the whole ceramic layer was measured.

An energy dispersive X-ray fluorescence analysis apparatus (EDX) was used as a measuring apparatus.

### (2.2) Measurement of Viscosity

As described above, the viscosity of each liquid mixture was measured during the making of each sample.

An oscillating viscometer (VM-10A-L manufactured by CBC Co., Ltd.) was used as a measuring apparatus.

### (2.3) Measurements of Thicknesses

A measuring position of each ceramic layer was scraped, and the heights (difference) before and after the scraping were measured.

A measuring microscope MF-A505H manufactured by Mitutoyo Corp. was used as a measuring apparatus.

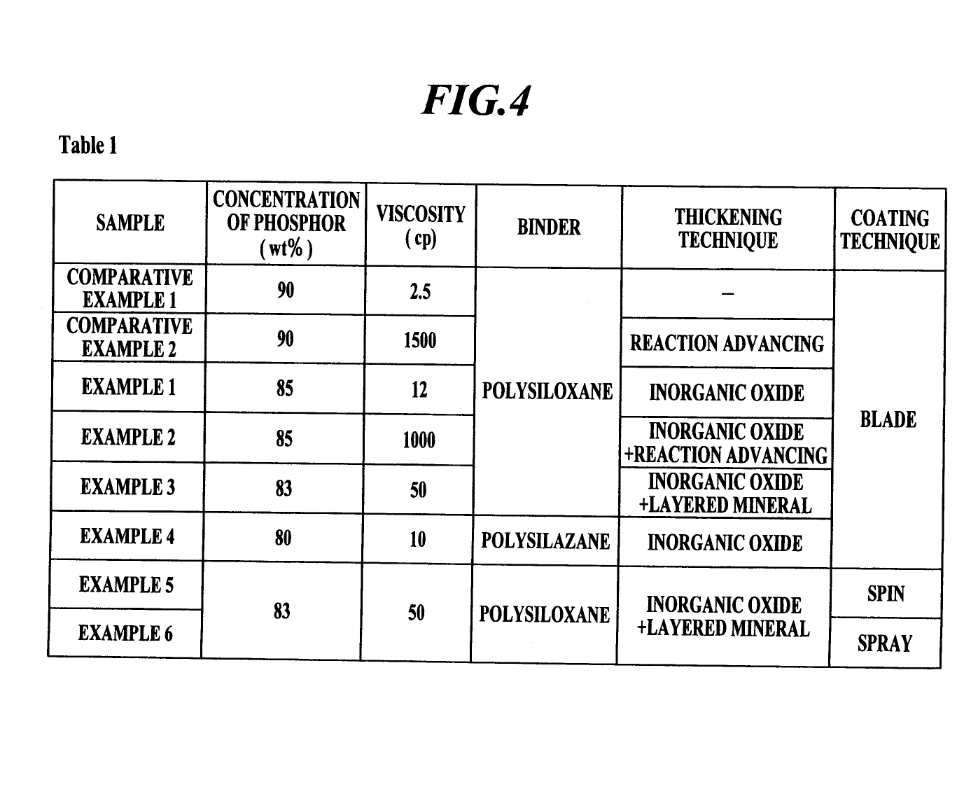

The measurement results and the like of the samples of the comparative examples 1 and 2 and the examples 1-6 are shown in a table 1 of FIG. 4 including the summary of each manufacturing method.

### (2.4) Measurements of Chromaticities

Each sample (glass substrate sized in 50 mm×50 mm) of the comparative examples 1 and 2 and the examples 1-6 are cut into a grid by the size of 5 mm×5 mm, and five cut pieces were arbitrarily selected among the cut pieces.

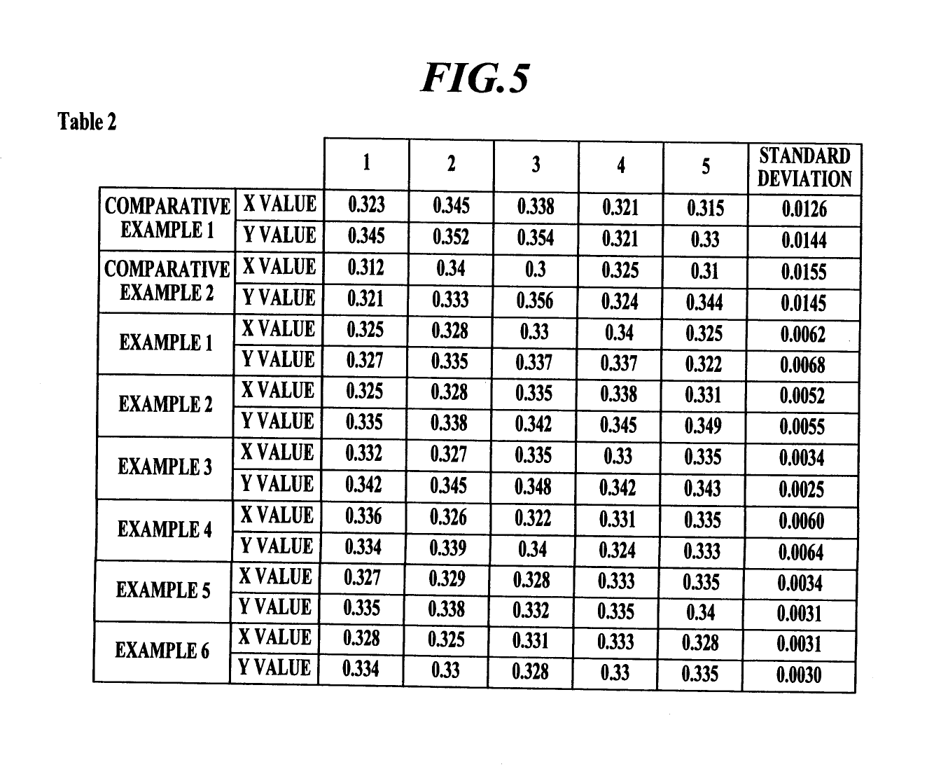

Each selected cut piece was mounted on each blue LED, and the chromaticities in two-dimensional directions (X direction and Y direction) of each cut piece when the LEDs emitted lights were measured. A spectral radiance meter CS-1000A manufactured by Konica Minolta Sensing, Inc. was used as a measuring apparatus. After that, standard deviations were calculated from measured values, and the uniformities of the chromaticities were compared and evaluated. It was supposed as an index of the evaluations that the dispersion of chromaticities had no problems practically when each standard deviation was equal to or less than 0.01. The results are shown in a table 2 of FIG. 5.

### (3) Conclusion

As shown in the table 2, the viscosity of the samples of the comparative examples 1 and 2 is not within a range of from 10 cp to 1000 cp, and the dispersion of the chromaticities are large.

The viscosity of the samples of the examples 1-3 is within the range of from 10 cp to 1000 cp, and the values equal to or less than 0.01 are obtained as the values of the standard deviations of the chromaticities. In particular, excellent results were obtained from the samples of the example 3.

The samples of the example 4 have the viscosity within the range of from 10 cp to 1000 cp and the value of the standard variation of the chromaticity is equal to or less than 0.01 although the samples use polysilazane as the ceramic precursors.

The samples of the examples 5 and 6 used the same materials as those of the samples of the example 3 and the coating techniques ware changed from those of the samples of the example 3, but good results were obtained from the samples of the examples 5 and 6.

From the examinations mentioned above, it was found that the adjustment of the viscosity of a mixture containing a ceramic precursor, a solvent, a phosphor, and the like to a certain viscosity (10-1000 cp) at the step of manufacturing a wavelength conversion element was useful for suppressing the changes of the chromaticities among wavelength conversion elements.

The entire disclosure of Japanese Patent Application No. 2010-109146 filed on May 11, 2010 including description, claims, drawings, and abstract are incorporated herein by reference in its entirety.

Although various exemplary embodiments have been shown and described, the invention is not limited to the embodiments shown. Therefore, the scope of the invention is intended to be limited solely by the scope of the claims that follow.

What is claimed is:

1. A manufacturing method of a wavelength conversion element including a substrate and a ceramic layer in which a phosphor is dispersed, the manufacturing method comprising the steps of:
preparing a mixture containing a ceramic precursor, a solvent, and the phosphor, the mixture having viscosity within a range of from 10 cp to 1000 cp;
coating the mixture on at least one surface of the substrate;
forming the ceramic layer by baking the mixture; and
dicing the substrate and the ceramic layer after the baking.

2. The manufacturing method according to claim 1, wherein, the step of preparing the mixture executes one of adding either of inorganic particles and layered silicate mineral to the mixture and increasing a molecular weight of the ceramic precursor in the mixture.

3. The manufacturing method according to claim 1, wherein the ceramic layer is composed of a ceramic having a siloxane bond as a backbone.

4. The manufacturing method according to claim 1, wherein a thickness of the ceramic layer is within a range of from 5 μm to 200 μm.

5. The manufacturing method according to claim 1, wherein the step of dicing the ceramic layer is executed in such a way that the ceramic layer is diced into polygons each having a side of 5 mm.

6. A wavelength conversion element manufactured by the manufacturing method according to any one of claims 1-5.

7. A light emitting device, comprising:
a wavelength conversion element manufactured by the manufacturing method according to anyone of claims 1-5; and
an LED element emitting a light of a specific wavelength to the wavelength conversion element.
